(19) United States
(12) Patent Application Publication
(10) Pub. No.: US 2026/0090148 A1
(43) Pub. Date: Mar. 26, 2026

(54) LIGHT-EMITTING DIODE AND LIGHT-EMITTING DEVICE

(71) Applicant: Tianjin Sanan Optoelectronics Co., Ltd., Tianjin (CN)

(72) Inventors: Zhiwei WU, Tianjin (CN); Yanyun WANG, Tianjin (CN); Zhuangshi LIU, Tianjin (CN); Huanshao KUO, Tianjin (CN); Yuren PENG, Tianjin (CN)

(21) Appl. No.: 19/336,666

(22) Filed: Sep. 23, 2025

(30) Foreign Application Priority Data
Sep. 24, 2024 (CN) 202411339487.6

(51) Int. Cl. H10H 20/84; H10H 20/814; H10H 20/821

(52) U.S. Cl. CPC H10H 20/84; H10H 20/814; H10H 20/821

(57) ABSTRACT

A light-emitting diode includes an epitaxial stack, a dielectric layer, a metal reflective layer, a substrate, and an oxide protective layer. The epitaxial stack sequentially includes a first semiconductor layer, a light-emitting layer, and a second semiconductor layer along a direction from an upper surface to a lower surface. The dielectric layer is disposed on the lower surface of the epitaxial stack and has multiple through-holes. The metal reflective layer is disposed on a side of the dielectric layer facing away from the epitaxial stack and electrically connected to the epitaxial stack through the through-holes. The substrate is disposed on a side of the metal reflective layer facing away from the epitaxial stack. The oxide protective layer covers a sidewall of the metal reflective layer. Thus, metal migration of the metal reflective layer can be effectively prevented, leakage current can be avoided, and the product quality can be improved.

### CROSS-REFERENCE TO RELATED APPLICATION

This application claims priority to Chinese patent application No. CN202411339487.6, filed to China National Intellectual Property Administration (CNIPA) on Sep. 24, 2024, which is herein incorporated by reference in its entirety.

### TECHNICAL FIELD

The disclosure relates to the field of semiconductor manufacturing technologies, and more particularly to a light-emitting diode and a light-emitting device.

### BACKGROUND

Light-emitting diode (LED) is a semiconductor light-emitting element, typically fabricated from semiconductor materials such as gallium nitride (GaN), gallium arsenide (GaAs), gallium phosphide (GaP), or gallium arsenide phosphide (GaAsP), with its core structure being a PN junction possessing light-emitting characteristics. LEDs offer advantages including high luminous intensity, high efficiency, compact size, and long operational lifetime, and are widely regarded as one of the most promising light sources available today. LEDs have been extensively applied in diverse fields such as general lighting, surveillance and command systems, high-definition broadcasting studios, premium cinemas, office displays, interactive conferencing, and virtual reality applications.

At present, in order to enhance light extraction efficiency of LED chips, a side of a metal bonding layer is usually provided with a metal reflective layer or an omnidirectional reflector (ODR) structure formed by a combination of the metal reflective layer and a dielectric layer, so that light emitted from the side of the metal bonding layer is reflected to a light-emitting side of an epitaxial stack, thereby improving the light extraction efficiency. Silver (Ag) is commonly selected for the metal reflective layer due to its high reflectivity and excellent thermal and electrical conductivity. However, Ag is inherently prone to migration, which can lead to current leakage in the chip. To address this issue, approaches in the related art involve patterning an Ag mirror and encapsulating its surface with a blocking layer. Such designs, however, typically increase the number of fabrication steps and process complexity, resulting in higher manufacturing costs.

It should be noted that the information disclosed in the background is provided solely to enhance the general understanding of the disclosure and should not be construed as an admission, or in any way implied, that such information constitutes related art generally known to those skilled in the art.

### SUMMARY

The disclosure provides a light-emitting diode, including an epitaxial stack, a dielectric layer, a metal reflective layer, a substrate, and an oxide protective layer. The epitaxial stack has an upper surface and a lower surface disposed in opposite, and the epitaxial stack sequentially includes a first semiconductor layer, a light-emitting layer, and a second semiconductor layer along a direction from the upper surface to the lower surface. The dielectric layer is disposed on the lower surface of the epitaxial stack and is defined with multiple through-holes. The metal reflective layer is disposed on a side of the dielectric layer facing away from the epitaxial stack and is electrically connected to the epitaxial stack through the multiple through-holes. The substrate is disposed on a side of the metal reflective layer facing away from the epitaxial stack. The oxide protective layer covers a sidewall of the metal reflective layer.

The disclosure further provides a light-emitting device, including the aforementioned light-emitting diode, and the light-emitting diode is implemented according to any of the embodiments described above.

The light-emitting diode and the light-emitting device provided by the disclosure effectively prevent metal migration in the metal reflective layer by disposing the oxide protective layer along its sidewall, without requiring patterning of the metal reflective layer or the additional formation of a separate blocking layer. The metal migration of the metal reflective layer can be effectively avoided, leakage current of the light-emitting diode is avoided, the quality of the light-emitting diode is improved, the process difficulty is simplified, and the production cost is reduced.

Other features and advantages of the disclosure will be set forth in the following detailed description. Furthermore, certain technical features and benefits will become readily apparent from the description, or may be learned through practice of the disclosure.

### BRIEF DESCRIPTION OF DRAWINGS

In order to more clearly illustrate technical solutions of embodiments of the disclosure or the related art, a brief introduction to the accompanying drawings, which are required for describing the embodiments or the related art, is provided below. It will be apparent that the drawings described herein depict only some embodiments of the disclosure. Those skilled in the art may, without inventive effort, derive other drawings based on the accompanying drawings.

FIG. 1 illustrates a schematic structural diagram of a light-emitting diode according to an embodiment of the disclosure.

FIG. 2 illustrates a partial enlarged view of FIG. 1.

FIG. 3 illustrates a schematic side view of a substrate according to the embodiment of the disclosure.

FIG. 4 illustrates a focused ion beam (FIB) image of the light-emitting diode according to the embodiment of the disclosure.

FIG. 5 illustrates a schematic structural diagram of a light-emitting diode according to another embodiment of the disclosure.

FIG. 6 illustrates a schematic side view of a substrate according to the another embodiment of the disclosure.

### DESCRIPTION OF REFERENCE SIGNS

10—epitaxial stack; 101—upper surface; 102—lower surface; 103—first semiconductor layer; 104—light-emitting layer; 105—second semiconductor layer; 12—passivation layer; 14—first electrode; 16—dielectric layer; 161—through-hole; 18—metal reflective layer; 20—bonding layer; 22—substrate; 24—second electrode; 26—current spreading layer; 31—first epitaxial sidewall; 32—second epitaxial sidewall; 40—oxide protective layer; 42—channel; 44—pore; 50—sidewall; A—corner point; B—angle; d1—distance from the corner point to an upper surface of the light-emitting layer; H1—thickness of the first semiconductor layer; W1—vertical projection length; W2—channel width; W3—projection width of the light-emitting diode; and S1—thickness of the oxide protective layer.

### DETAILED DESCRIPTION OF EMBODIMENTS

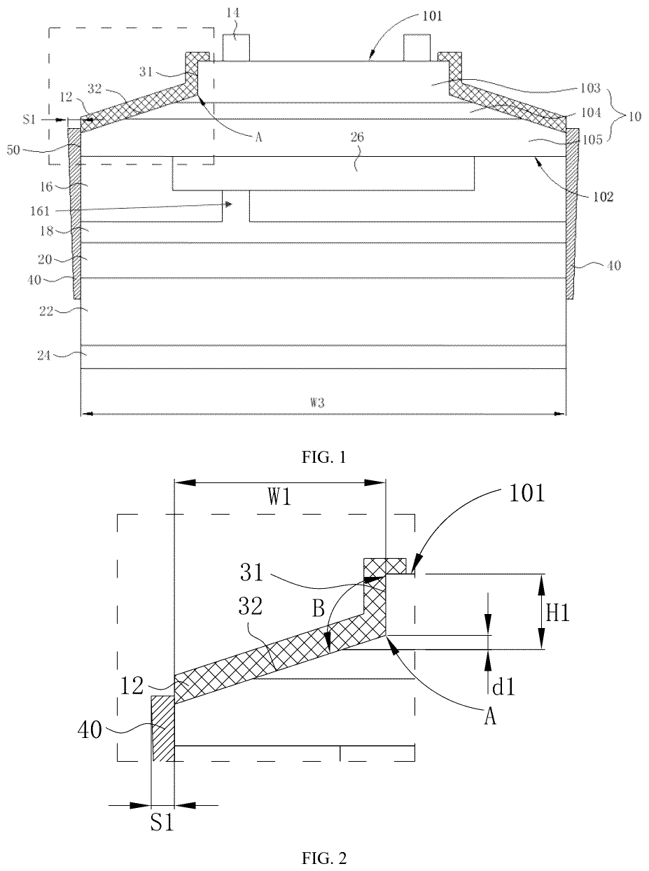

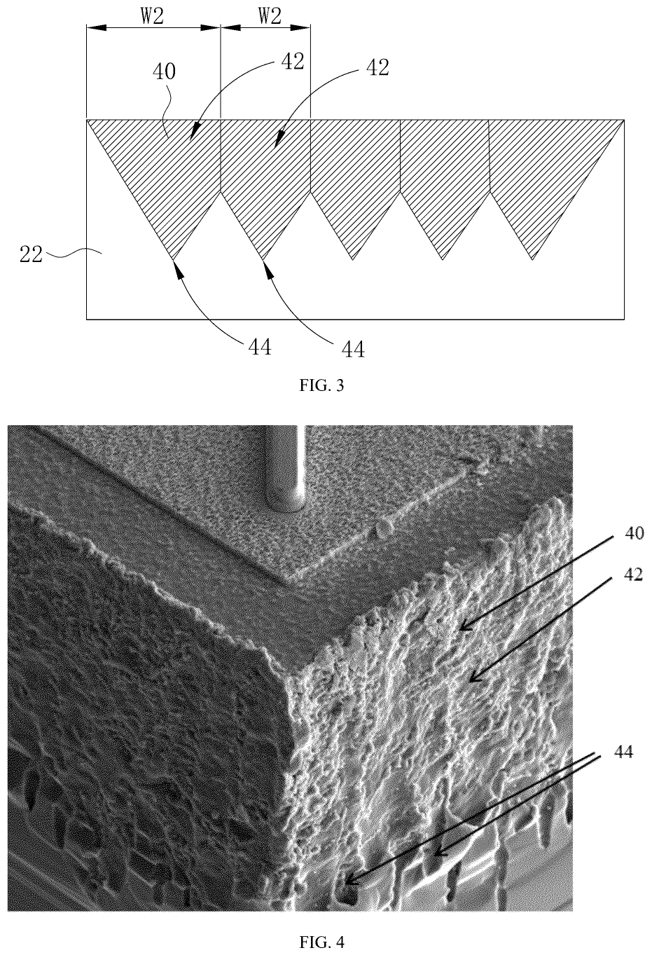

Referring to FIG. 1 to FIG. 4, FIG. 1 illustrates a schematic structural diagram of a light-emitting diode according to an embodiment of the disclosure; FIG. 2 illustrates a partial enlarged view of FIG. 1; FIG. 3 illustrates a schematic side view of a substrate 22 according to the embodiment of the disclosure; and FIG. 4 illustrates a focused ion beam (FIB) image of the light-emitting diode according to the embodiment of the disclosure. It should be noted that FIG. 3 can be understood as a schematic structural diagram of the substrate 22 when viewing the light-emitting diode of FIG. 1 from a left side towards a right side. The FIB image refers to an image presented by microscopic analysis of the light-emitting diode using FIB technology.

To achieve at least one of the aforementioned advantages or other advantages, a first embodiment of the disclosure provides a light-emitting diode. As shown in FIG. 1 to FIG. 4, the light-emitting diode includes an epitaxial stack 10, a dielectric layer 16, a metal reflective layer 18, a substrate 22, and an oxide protective layer 40.

The epitaxial stack 10 has an upper surface 101 and a lower surface 102 disposed in opposite. The epitaxial stack 10 sequentially includes a first semiconductor layer 103, a light-emitting layer 104, and a second semiconductor layer 105 along a direction from the upper surface 101 to the lower surface 102.

The epitaxial stack 10 can be formed on a growth substrate by methods such as physical vapor deposition (PVD), chemical vapor deposition (CVD), epitaxy growth technology, or atomic layer deposition (ALD). The first semiconductor layer 103 and the second semiconductor layer 105 are semiconductors with different conductivity types, electrical properties, or polarities, which provide electrons or holes depending on doped elements. For example, when the first semiconductor layer 103 is n-type, the second semiconductor layer 105 is p-type, the light-emitting layer 104 is formed between the first semiconductor layer 103 and the second semiconductor layer 105. The electrons and holes are driven by a current to recombine within the light-emitting layer 104 and convert electrical energy into light energy to emit light. A wavelength of the light emitted by the light-emitting diode is adjusted by changing the physical and chemical composition of one or more layers of the epitaxial light-emitting layer 104, and vice versa. In this embodiment, the light-emitting diode with the first semiconductor layer 103 being n-type and the second semiconductor layer 105 being p-type is taken as an example.

The light-emitting layer 104 is a region where the electrons and holes recombine to provide optical radiation. Different materials can be selected based on different light-emitting wavelengths. The light-emitting layer 104 can be a single heterostructure (SH), a double heterostructure (DH), a double-sided double heterostructure (DDH), or a multiple quantum well (MQW) structure. The light-emitting layer 104 includes well layers and barrier layers, where the barrier layers have a larger band gap than the well layers. By adjusting a composition ratio of semiconductor materials in the light-emitting layer 104, it is expected to emit light of different wavelengths. In this embodiment, the semiconductor epitaxial stack 100 is a semiconductor material layer capable of radiating light such as ultraviolet, blue, green, yellow, red, or infrared light, specifically materials in a range of 200 nanometers (nm) to 950 nm. For example, the materials include nitrides, such as GaN-based semiconductor epitaxial stacks, the GaN-based semiconductor epitaxial stacks are commonly doped with elements such as aluminum or indium, primarily providing radiation in the 200-550 nm band. Alternatively, the nitrides are, for example, aluminum gallium indium phosphide (AlGaInP)-based or aluminum gallium arsenide (AlGaAs)-based semiconductor epitaxial stacks mainly provide radiation in the 550-950 nm band. To improve light-emitting efficiency, the depth of quantum wells, the number of pairs of quantum wells and quantum barriers, the thickness, and/or other characteristics within the light-emitting layer 104 can be modified. In this embodiment, the epitaxial stack 10 is specifically composed of AlGaInP-based or GaAs-based materials.

The dielectric layer 16 is disposed on the lower surface 102 of the epitaxial stack 10. The dielectric layer 16 has multiple conductive through-holes 161. The multiple through-holes 161 can expose the epitaxial stack 10. The dielectric layer 16 is light-transmissive. A material of the dielectric layer 16 may include transparent compounds such as silicon nitride, silicon oxide, titanium oxide, and their laminated combinations, for example, a distributed Bragg reflector (DBR) formed by repeated stacking of two materials with different refractive indices.

The metal reflective layer 18 is disposed on a side of the dielectric layer 16 facing away from the epitaxial stack 10. The metal reflective layer 18 is electrically connected to the epitaxial stack 10 through the through-holes 161. The metal reflective layer 18 can be made of metal materials. The metal reflective layer 18 can have a reflectivity of over 90% and can be formed from a metal or an alloy including at least one of silver, nickel, aluminum, rhodium, palladium, iridium, ruthenium, magnesium, titanium, chromium, zinc, platinum, gold, and hafnium. This metal reflective layer 18 can reflect light radiated from the epitaxial stack 10 towards a side of the substrate 22 back to the epitaxial stack 10, and radiate the light from a side of the light-emitting surface.

The substrate 22 is disposed on a side of the metal reflective layer 18 facing away from the epitaxial stack 10. The substrate 22 is a conductive substrate. The conductive substrate can be silicon, silicon carbide, aluminum nitride, or a metal substrate. The metal substrate is specifically a copper substrate, a tungsten substrate, a copper-tungsten substrate, or a molybdenum substrate. To provide sufficient mechanical strength to support the epitaxial stack 10, the thickness of the substrate 22 can be over 50 micrometers (μm).

The oxide protective layer 40 covers the sidewall of the metal reflective layer 18. A material of the oxide protective layer 40 is different from that of the passivation layer 12. The material of the oxide protective layer 40 may include silicon oxide, doped with at least one element from the group consisting of gallium, indium, tin, nickel, titanium, platinum, and gold. That is, the oxide protective layer 40 is doped with at least one or more compounds or elemental substances composed of elements such as gallium, indium, tin, nickel, titanium, platinum, gold, etc. In some embodiments, the oxide protective layer 40 can be formed by laser dicing of the chip. For example, during the laser dicing process, the laser irradiates the chip's scribe line, some components of the chip are shattered and melted due to the high intensity of the laser and are splashed onto the surrounding sidewall, generating oxidation products in the process. These oxidation products adhere to the sidewall and form an oxide protective layer 40 with a certain thickness, which covers the sidewall of the metal reflective layer 18. By setting the oxide protective layer 40, it is no longer necessary to pattern the metal reflective layer 18 or additionally provide a blocking layer. The metal migration of the metal reflective layer can be effectively avoided, leakage current of the light-emitting diode is avoided, the quality of the light-emitting diode is improved, the process difficulty is simplified, and the production cost is reduced.

In some embodiments, to further prevent metal migration, an upper surface of the oxide protective layer 40 is not lower than a lower surface of the second semiconductor layer 105. A lower surface of the oxide protective layer 40 is not higher than an upper surface of the substrate 22. The upper surface and the lower surface of the oxide protective layer 40 may refer to surfaces where its highest and lowest points are located.

In some embodiments, the upper surface of the oxide protective layer 40 is higher than the lower surface of the second semiconductor layer 105. The oxide protective layer 40 extends upward from the lower surface of the second semiconductor layer 105 to a position higher than the upper surface of the second semiconductor layer 105.

In some embodiments, the height of the upper and lower surfaces of the oxide protective layer 40 can be adjusted by controlling the laser intensity. The laser power can be 2-10 Watts (W). The higher the laser power, i.e., the greater the laser intensity, the more oxide is produced, and the higher the upper surface. Similarly, high-intensity laser strikes deeper, allowing the oxide protective layer 40 to have a lower surface. Conversely, the oxide protective layer 40 formed by weaker laser will not be very deep. The laser power can be adjusted according to requirements to obtain an oxide protective layer of suitable specifications.

In some embodiments, the oxide protective layer 40 has a maximum thickness at one location. A thickness S1 of the oxide protective layer 40 gradually decreases from the location of the maximum thickness toward the substrate 22 until it reaches a minimum thickness and then remains unchanged. This structure is formed due to laser dicing. The area where the laser is strongest experiences the most shattering and splashing, thus generating the most oxide nearby. Areas with the weakest laser have almost no such oxide. The oxide protective layer 40 with a gradually varying thickness does not require additional processes. The oxide protective layer 40 can be generated in one step during laser dicing, greatly simplifying the process difficulty and providing the advantage of protecting the metal reflective layer 18. Similarly, the thickness S1 of the oxide protective layer 40 gradually decreases from the location of the maximum thickness towards the direction of the upper surface 101 of the epitaxial stack 10 until it reaches the minimum thickness and then remains unchanged. The location of the maximum thickness of the oxide protective layer 40 may be located in the sidewall region of the second semiconductor layer 105.

In some embodiments, as shown in FIG. 1, a projection width W3 of the light-emitting diode on a horizontal plane is smallest at the second semiconductor layer 105. This projection width W3 gradually increases from its minimum width towards the direction of the substrate 22. It should be noted that, as shown in the FIG. 1, this projection width W3 excludes the oxide protective layer 40, i.e., it represents the width variation of the light-emitting diode after removing the oxide protective layer 40. Due to the laser dicing process, this change in the projection width W3 occurs because the stronger the laser energy, the more material is removed from the side of the original light-emitting diode at the second semiconductor layer 105, leaving less remaining material, thus reducing the projection width W3. Furthermore, when the projection width W3 reaches its maximum width, the subsequent laser intensity is nearly absent, so the projection width W3 remains almost unchanged after reaching the maximum width.

In some embodiments, the light-emitting diode has a sidewall 50. The thickness of the sidewall 50 is smallest at the second semiconductor layer 105. The thickness of the sidewall 50 gradually increases from its minimum thickness towards the direction of the substrate 22. It should be noted that this sidewall 50 excludes the oxide protective layer 40. For example, the sidewall 50 may refer to the sidewall starting from the sidewall of the second semiconductor layer 105, extending downward through the sidewall of the dielectric layer 16, the sidewall of the metal reflective layer 18, the sidewall of the bonding layer 20, until extending to the sidewall of the substrate 22. In some embodiments, when the thickness of the sidewall 50 gradually increases towards the substrate 22, it ceases to change after reaching its maximum thickness. Due to the laser dicing process, the stronger the laser energy, the more material is removed from the sidewall 50 of the original light-emitting diode, leaving less remaining material, and when the thickness of the sidewall 50 reaches its maximum thickness, the subsequent laser intensity is nearly absent, so the thickness of the sidewall 50 remains almost unchanged thereafter.

In some embodiments, referring to FIG. 3 and FIG. 4, multiple channels 42 are defined on the sidewall of the substrate 22, and the oxide protective layer 40 fills the channels 42. Each channel 42 has a maximum width. A width W2 (i.e., channel width W2) of each channel 42 gradually decreases from a location of the maximum width towards a direction of a lower surface of the substrate 22. Correspondingly, as shown in FIG. 3 and FIG. 4, the width W2 of each channel 42 narrows from top to bottom. Adjacent channels 42 are interconnected to each other at their locations of maximum width, meaning upper portions of the channels 42 are interconnected, forming an integral part. The maximum width of each channel 42 is usually the width at its upper surface. A bottom end of each channel 42 forms a pore 44. The width of the channel 42 at the pore 44 is the smallest, that is, the width at the bottom end of the channel 42 is the smallest. Referring to the illustrated shape in FIG. 3, a shape from the location of minimum width of the channel 42 to the location of maximum width of the channel 42 is like V-shaped. It should be noted that, in FIG. 3, for the purpose of easily understanding the correspondence between the channels 42 and the pores 44, and the change in the width W2 of the channel 42, etc., only relatively symmetrical, one-to-one correspondence between each channel 42 and pore 44 is schematically shown. However, the disclosure is not limited to this. In actual situations, various channels 42 and pores 44 may exist in multiple conditions, such as inconsistent heights of adjacent pores 44, inconsistent maximum widths of various channels 42, or inconsistent regions of maximum width for various channels 42, etc. But for the same channel 42, the channel 42 and its pore 44 must satisfy the aforementioned width change relationship.

In some embodiments, as shown in FIG. 4, a surface morphology of the oxide protective layer 40 has a fish-scale-like texture. This fish-scale-like texture may be composed of multiple flake-like units arranged together. There are certain thickness differences and height differences between the flake units, meaning the thicknesses and heights of respective flake units may be uneven and irregularly distributed. The reason for its formation is: in the process of laser dicing the chip, multiple lasers of 2-10 W are used. The first laser forms the first channel, the second laser forms the second channel and splashes some oxide onto the adjacent first/third channels, and so on. Each channel will have some oxide splashed from other parts, eventually forming a layered, irregular fish-scale-like texture. This fish-scale-like oxide protective layer 40 can well protect the metal reflective layer 18.

In some embodiments, the light-emitting diode may further include a passivation layer 12, a first electrode 14, a bonding layer 20, and a second electrode 24.

The passivation layer 12 is partially disposed on an outer side of the epitaxial stack 10, mainly serving a protection and isolation function. A material of the passivation layer 12 may include silicon oxide, etc. A sidewall morphology of the passivation layer 12 may be the same as a morphology formed after connecting the first epitaxial sidewall 31 to the second epitaxial sidewall 32.

The first electrode 14 is disposed on the upper surface 101 of the epitaxial stack 10. The first electrode 14 can be a single-layer structure, a double-layer structure, or a multi-layer structure. A material of the first electrode 14 can be a metal material, such as chromium, platinum, gold, nickel, titanium, aluminum, etc.

The bonding layer 20 is disposed between the metal reflective layer 18 and the substrate 22. The bonding layer 20 is used for the substrate 22 and the epitaxial stack 10 to enhance the overall structural connection strength. The bonding layer 20 can use metal elements such as gold, tin, titanium, tungsten, nickel, platinum, indium, etc. This bonding layer 20 can be a single-layer or a multi-layer structure and can be a combination of multiple materials.

The second electrode 24 is disposed on a side of the substrate 22 facing away from the epitaxial stack 10. The second electrode 24 can be made of metal material.

In some embodiments, a current spreading layer 26 can further be disposed below the second semiconductor layer 105. The current spreading layer 26 serves to spread current. A material of the current spreading layer 26 may include gallium phosphide, etc. The dielectric layer 16 covers the current spreading layer 26. The through-holes 161 of the dielectric layer 16 expose a part of the current spreading layer 26, and the metal reflective layer 18 is electrically connected to the current spreading layer 26 through the through-holes 161.

The epitaxial stack 10 has a first epitaxial sidewall 31 and a second epitaxial sidewall 32 on the same side. As shown in FIG. 2, the first epitaxial sidewall 31 and the second epitaxial sidewall 32 on the left side are used as an example for description. The first epitaxial sidewall 31 is a partial sidewall located on the first semiconductor layer 103. The second epitaxial sidewall 32 is a sidewall extending from a partial sidewall of the second semiconductor layer 105 towards a direction of the upper surface 101 of the epitaxial stack 10, passing through a sidewall of the light-emitting layer 104 until extending to a sidewall of the first semiconductor layer 103. That is, the second epitaxial sidewall 32 is composed of the partial sidewall of the second semiconductor layer 105, the sidewall of the light-emitting layer 104, and the partial sidewall of the first semiconductor layer 103. Furthermore, the first epitaxial sidewall 31 is connected to the second epitaxial sidewall 32, a corner point A is formed at connection between the first epitaxial sidewall 31 and the second epitaxial sidewall 32, and an angle B is formed at this corner point A, where the angle B is greater than 90°. Compared to the traditional right-angled L-shaped sidewall, the disclosure forms an inclined two-segment sidewall by setting the corner point A, and this corner point A is located on the sidewall of the first semiconductor layer 103 above the light-emitting layer 104. In this situation, after the chip dicing process, the organic matter is easier to clean thoroughly during the degumming process, and the continuity of the subsequent other protective layers covering the sidewall is facilitated. Moreover, since the corner point A is set at the first semiconductor layer 103, the light-emitting layer 104 and the second semiconductor layer are not exposed. In this way, even if some organic substances remain, the problem of electric leakage burn can be avoided, and the light-emitting layer 104 can be ensured to have a flat surface, so that the organic substances are not easy to remain, thereby reducing the risk of electric leakage. Alternatively, the first epitaxial sidewall 31 is the part extending from the upper surface 101 of the epitaxial stack 10 towards the lower surface 102 of the epitaxial stack 10 to the corner point A, and the corner point A is located on the sidewall of the first semiconductor layer 103. Alternatively, considering the impact on light-emitting effect, the range of angle B can be in a range of 91° to 120°.

In some embodiments, a distance from the corner point A to the upper surface of the light emitting layer 104 is defined as d1, and a thickness of the first semiconductor layer 103 is defined as H1, where the distance d1 is greater than or equal to 0.05H1 and the distance d1 is less than or equal to 0.4H1, where H1 is a thickness of the first semiconductor layer. If the distance d1 is less than 0.05H1, it means the corner point A is too close to the light-emitting layer 104, and organic matter may still adhere the vicinity of the light-emitting layer 104, easily causing a leakage problem. If the distance d1 is greater than 0.4H1, it means the corner point A is positioned too high, causing a dicing line to be too narrow, which is not conducive to the implementation of subsequent processes.

In some embodiments, taking the upper surface 101 of the epitaxial stack 10 as a reference plane, an angle between an extension line of the first epitaxial sidewall 31 and the upper surface 101 of the epitaxial stack 10 is in a range of 80° to 100°. In an illustrated embodiment, this angle is 90°, meaning the first epitaxial sidewall 31 is perpendicular to the upper surface 101 of the epitaxial stack 10.

In some embodiments, a vertical projection length W1 of the second epitaxial sidewall 32 located on a side of the epitaxial stack 10 on the lower surface 102 of the epitaxial stack 10 is a range of 10 μm to 30 μm. That is, the overall width W1 of the second epitaxial sidewall 32 in a horizontal direction is in a range of 10 μm to 30 μm. Conversely, if the overall width W1 is greater than 30 μm, the remaining light-emitting layer 104 is too small, which is not conducive to light-emitting efficiency. If the overall width W1 is less than 10 μm, the dicing line is too narrow, which is not conducive to the subsequent dicing process.

In some embodiments, the second epitaxial sidewall 32 extends at least over the entire second semiconductor layer 105. For example, the second epitaxial sidewall 32 may further extend downward to the underlying dielectric layer 16, etc.

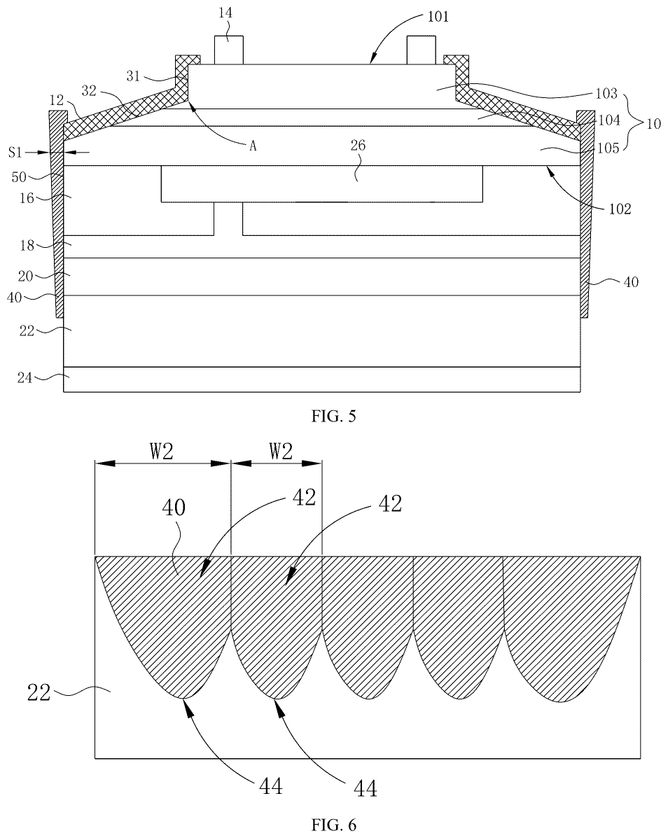

Referring to FIG. 5, FIG. 5 illustrates a schematic structural diagram of a light-emitting diode according to another embodiment of the disclosure. Compared to the light-emitting diode shown in FIG. 1, the main difference in this embodiment is that the oxide protective layer 40 extends upward to cover part of the passivation layer 12, meaning the oxide protective layer 40 envelops a part of the passivation layer 12.

Referring to FIG. 6, FIG. 6 illustrates a schematic side view of a substrate according to the another embodiment of the disclosure. Compared to FIG. 3, the main difference in this embodiment is that the shape from the location of the minimum width of the channel 42 to the location of the maximum width of the channel 42 in this embodiment is U-shaped.

An embodiment of the disclosure also provides a light-emitting device, which includes a light-emitting diode. The light-emitting diode can adopt the light-emitting diode described in any of the above embodiments.

In summary, the light-emitting diode and the light-emitting device provided by the embodiments of the disclosure, by providing an oxide protective layer 40 on the sidewall of the metal reflective layer 18, effectively prevent metal migration in the metal reflective layer 18 without requiring patterning of the metal reflective layer or the additional formation of a separate blocking layer. The metal migration of the metal reflective layer can be effectively avoided, leakage current of the light-emitting diode is avoided, the quality of the light-emitting diode is improved, the process difficulty is simplified, and the production cost is reduced.

What is claimed is:

1. A light-emitting diode, comprising:
an epitaxial stack, having an upper surface and a lower surface disposed in opposite, wherein the epitaxial stack sequentially comprises a first semiconductor layer, a light-emitting layer, and a second semiconductor layer along a direction from the upper surface to the lower surface;
a dielectric layer, disposed on the lower surface of the epitaxial stack and defined with a plurality of through-holes;
a metal reflective layer, disposed on a side of the dielectric layer facing away from the epitaxial stack, wherein the metal reflective layer is electrically connected to the epitaxial stack through the plurality of through-holes;
a substrate, disposed on a side of the metal reflective layer facing away from the epitaxial stack; and
an oxide protective layer, covering a sidewall of the metal reflective layer.

2. The light-emitting diode as claimed in claim 1, wherein an upper surface of the oxide protective layer is not lower than a lower surface of the second semiconductor layer.

3. The light-emitting diode as claimed in claim 1, wherein a lower surface of the oxide protective layer is not higher than an upper surface of the substrate.

4. The light-emitting diode as claimed in claim 1, wherein an upper surface of the oxide protective layer is higher than a lower surface of the second semiconductor layer, and the oxide protective layer extends upward from a lower surface of the second semiconductor layer to a position higher than an upper surface of the second semiconductor layer.

5. The light-emitting diode as claimed in claim 1, wherein a material of the oxide protective layer comprises silicon oxide, and the oxide protective layer is doped with at least one element selected from the group consisting of gallium, indium, tin, nickel, titanium, platinum, and gold.

6. The light-emitting diode as claimed in claim 1, wherein a surface morphology of the oxide protective layer exhibits a fish-scale-like texture, the fish-scale-like texture is composed of a plurality of flake-like units arranged in a pattern, and adjacent flake-like units exhibit a thickness difference and a height difference.

7. The light-emitting diode as claimed in claim 1, wherein the oxide protective layer has a maximum thickness at one location, and a thickness of the oxide protective layer gradually decreases from the location of the maximum thickness toward the substrate.

8. The light-emitting diode as claimed in claim 1, wherein the oxide protective layer has a maximum thickness at one location, and a thickness of the oxide protective layer gradually decreases from the location of the maximum thickness toward the upper surface of the epitaxial stack.

9. The light-emitting diode as claimed in claim 1, wherein a projection width of the light-emitting diode in a horizontal plane has a minimum width at the second semiconductor layer, and the projection width gradually increases from a location of the minimum width toward the substrate.

10. The light-emitting diode as claimed in claim 1, wherein a sidewall of the substrate is defined with a plurality of channels, the oxide protective layer fills the plurality of channels, each channel has a maximum width, and a width of each channel gradually decreases from a location of the maximum width of each channel toward a lower surface of the substrate.

11. The light-emitting diode as claimed in claim 10, wherein adjacent channels of the plurality of channels are interconnected at respective locations of the maximum width of the adjacent channels of the plurality of channels.

12. The light-emitting diode as claimed in claim 10, wherein each channel terminates at a bottom end forming a pore, and each channel has a minimum width at the pore.

13. The light-emitting diode as claimed in claim 10, wherein a shape of each channel is V-shaped or U-shaped from a location of a minimum width to a location of the maximum width.

14. The light-emitting diode as claimed in claim 1, further comprising a passivation layer, a first electrode, a bonding layer, and a second electrode; wherein:
a part of the passivation layer is disposed on an outer side of the epitaxial stack;
the first electrode is disposed on the upper surface of the epitaxial stack;
the bonding layer is disposed between the metal reflective layer and the substrate; and
the second electrode is disposed on a side of the substrate facing away from the epitaxial stack.

15. The light-emitting diode as claimed in claim 1, wherein the epitaxial stack has a first epitaxial sidewall and a second epitaxial sidewall on a same side, the first epitaxial sidewall is a partial sidewall located on the first semiconductor layer, and the second epitaxial sidewall is a sidewall extending from a partial sidewall of the second semiconductor layer upward toward the upper surface of the epitaxial stack, passing through a sidewall of the light-emitting layer, and extending to a sidewall of the first semiconductor layer; the first epitaxial sidewall is connected to the second epitaxial sidewall, a corner point is formed at connection between the first epitaxial sidewall and the second epitaxial sidewall, and an angle formed at the corner point is greater than 90°.

16. The light-emitting diode as claimed in claim 15, wherein the first epitaxial sidewall extends from the upper surface of the epitaxial stack downward to the corner point, and the corner point is located on the sidewall of the first semiconductor layer.

17. The light-emitting diode as claimed in claim 15, wherein the angle is in a range of 91° to 120°.

18. The light-emitting diode as claimed in claim 15, wherein a distance d1 from the corner point to an upper surface of the light-emitting layer satisfies a relationship: the distance d1 is greater than or equal to 0.05H1 and the distance d1 is less than or equal to 0.4H1, where H1 is a thickness of the first semiconductor layer.

19. The light-emitting diode as claimed in claim 15, wherein, with reference to the upper surface of the epitaxial stack as a reference plane, an angle between an extension line of the first epitaxial sidewall and the upper surface of the epitaxial stack is in a range of 80° to 100°.

20. A light-emitting device, comprising: the light-emitting diode as claimed in claim 1.
